(19) United States
(12) Patent Application Publication
(10) Pub. No.: US 2020/0162064 A1
(43) Pub. Date: May 21, 2020

(54) DEBOUNCE CIRCUIT USING D FLIP-FLOPS

(71) Applicants: Inventec (Pudong) Technology Corp., Shanghai (CN); Inventec Corporation, Taipei (TW)

(72) Inventors: Chun-Chieh Lu, Taipei (TW); Tsung-Hsi Lee, Taipei (TW)

(21) Appl. No.: 16/221,570

(22) Filed: Dec. 16, 2018

(30) Foreign Application Priority Data
Nov. 21, 2018 (CN) 201811388021.X

(51) Int. Cl. H03K 5/1254; H03K 3/013

(52) U.S. Cl. CPC H03K 5/1254; H03K 3/013

(57) ABSTRACT

A debounce circuit includes a sampling circuit to sample an input signal four times at two adjacent rising edges and two adjacent falling edges of a first clock signal to determine a voltage level of the first output signal, a voltage level of the second output signal, a voltage level of the third output signal and a voltage level of the fourth output signal, and a logic gate for performing an AND operation or an OR operation on the first output signal, the second output signal, the third output signal, and the fourth output signal to output a debounced signal. The first clock signal has at least one of the two adjacent rising edges between the two adjacent falling edges and at least one of the two adjacent falling edges between the two adjacent rising edges.

### BACKGROUND OF THE INVENTION

### 1. Field of the Invention

The present invention is related to a debounce circuit, and particularly to a debounce circuit adopting D flip-flops.

### 2. Description of the Prior Art

During a system control process, signals are transmitted between components where the output signal of the previous stage usually serves as the input signal of the next stage. However, during transmitting signals, the signals output from the components, such as the signals input by a keyboard or keys, are not ones with ideal and perfect waveforms. According to the physical nature, when a characteristic or an electrical level is instantly changed, it is unable to change the state immediately. Instead, a reaction is produced, and before the signal enters the stable output state, a bounce phenomenon occurs where multiple digits 0 and 1 alternately move up and down in view of digital signal. The phenomenon makes the system treat the signal at the input terminal thereof as a continuous input signal, which leads a state misjudgement and an error message.

In particular for some devices of a system, in terms of the setting of logic judgment, once a state-changing phenomenon is detected out, the system would enter a phase to process the voltage or the error message. Even further, an unstable signal may cause a system shutdown or crash. In this regard, prior to inputting the output signals of the devices to the components of the next stage, a debounce circuit is used to debounce the signals such that the input signals are transferred to the output signals through a debounce delay buffer until the state gets stable; and at the time, the signals are input to the components of the next stage.

The debounce circuit of the prior art usually takes samples of an input signal, and the sampling frequency must be more than ten times higher than the frequency of the input signal. When the input signal is in transition (for example, from logic value 0 to 1 or from 1 to 0) and the sampled input signal contains consecutive is or Os, the system determines that the input signal has reached to a steady state and can output the debounced signal.

However, the sampling frequency required for the debounce circuit of the prior art must be more than ten times higher than the frequency of the input signal. For some electronic devices, it is not possible to provide the signal with such high sampling frequency. Further, since the conventional debounce circuit must continuously sample a certain number of consecutive is or Os to confirm that the input signal has reached to a steady state, the setup time of the device is shortened due to oversampling. When the setup time is shortened excessively, it may cause the components to receive erroneous signals.

### SUMMARY OF THE INVENTION

An embodiment discloses a debounce circuit comprising a sampling circuit to sample an input signal four times at two adjacent rising edges and two adjacent falling edges of a first clock signal to determine a voltage level of the first output signal, a voltage level of the second output signal, a voltage level of the third output signal and a voltage level of the fourth output signal, and a logic gate for performing an AND operation or an OR operation on the first output signal, the second output signal, the third output signal, and the fourth output signal to output a debounced signal. The first clock signal has at least one of the two adjacent rising edges between the two adjacent falling edges and at least one of the two adjacent falling edges between the two adjacent rising edges.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of a debounce circuit according to an embodiment.

FIG. 2 shows a timing diagram of various signals of the debounce circuit in FIG. 1.

FIG. 3 shows waveforms of four signals including the input signal Sw and the debounced signal Db1.

FIG. 4 is a circuit diagram of a debounce circuit of another embodiment.

FIG. 5 is a timing diagram of various signals of the debounce circuit in FIG. 4.

### DETAILED DESCRIPTION

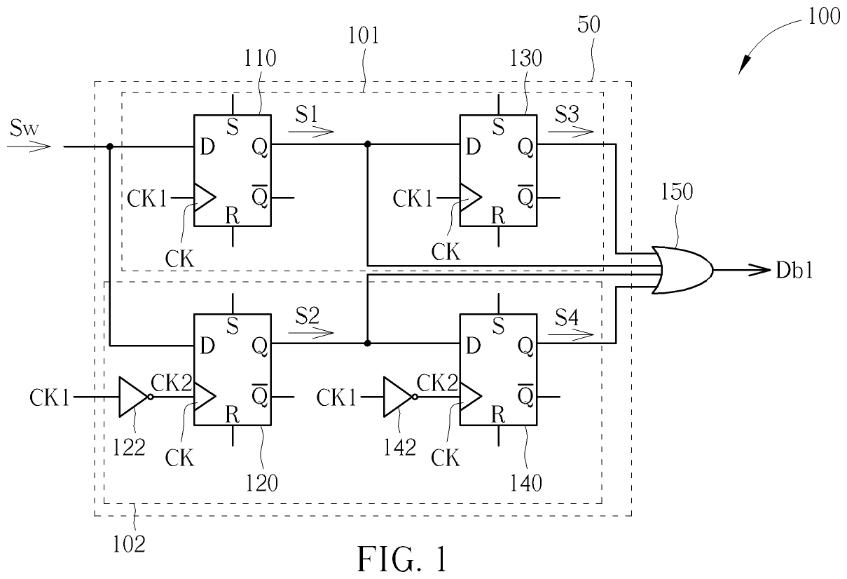

FIG. 1 is a circuit diagram for a debounce circuit 100 of an embodiment. The debounce circuit 100 is used to perform a debouncing process on an input signal Sw from a signal transmitter to generate a debounced signal Db1 and transmit the debounced signal Db1 to a signal receiver. The debounce circuit 100 includes a sampling circuit 50 and a logic gate 150. The sampling circuit 50 is configured to sample the input signal Sw four times at two adjacent rising edges and two adjacent falling edges of a first clock signal CK1 to determine voltage levels of a first output signal S1, a second output signal S2, a third output signal S3, and a fourth output signal S4. At least one of the two adjacent rising edges is between the two adjacent falling edges, and at least one of the two adjacent falling edges is between the two adjacent rising edges. The logic gate 150 is used to perform an AND operation or an OR operation on the first output signal S1, the second output signal S2, the third output signal S3, and the fourth output signal S4 to output an debounced signal Db1.

In an embodiment, the sampling circuit 50 includes a rising edge trigger module 101 and a falling edge trigger module 102. The rising edge trigger module 101 is used to sample the input signal Sw to determine the voltage level of the first output signal S1 and sample the first output signal S1 to determine the voltage level of the third output signal S3 when the first clock signal CK1 is at the rising edge. The falling edge trigger module 102 is used to sample the input signal Sw to determine the voltage level of the second output signal S2 and sample the second output signal S2 to determine the voltage level of the fourth output signal S4 when the first clock signal CK1 is at the falling edge.

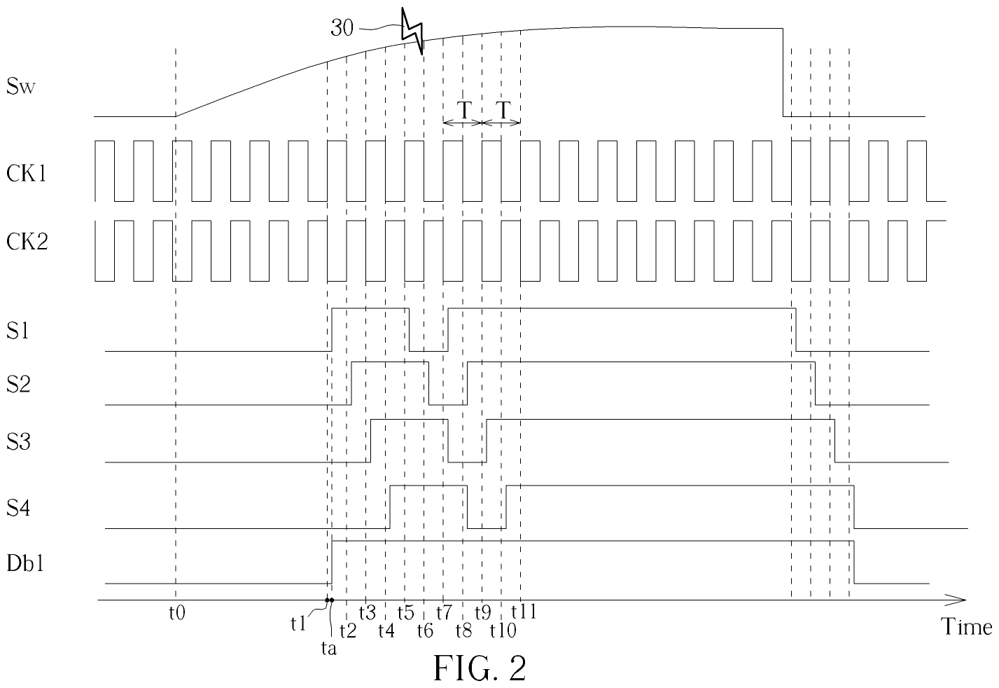

FIG. 2 is a timing diagram of various signals of the debounce circuit 100 in FIG. 1. The rising edge trigger module 101 samples the input signal Sw and the first output signal S1 at the rising edges of the first clock signal CK1 to determine the voltage level of the first output signal S1 and the voltage level of the third output signal S3. Therefore, the waveform of the third output signal S3 will lag behind the waveform of the first output signal S1 by a period T of the first clock signal CK1. Therefore, the third output signal S3 is the result of the rising edge trigger module 101 sampling the input signal Sw at the previous rising edge of the first clock signal CK1. In contrast, the first output signal S1 is the result of the rising edge trigger module 101 sampling the input signal Sw at the current rising edge of the first clock signal CK1. Similarly, the falling edge trigger module 102 samples the input signal Sw and the second output signal S2 at the falling edges of the first clock signal CK1 to determine the voltage level of the second output signal S2 and the voltage level of the fourth output signal S4. Therefore, the waveform of the fourth output signal S4 will lag behind the waveform of the second output signal S2 by a period T of the first clock signal CK1. The fourth output signal S4 is the result of the falling edge trigger module 102 sampling the input signal Sw at the previous falling edge of the first clock signal CK1. In contrast, the second output signal S2 is the result of the falling edge trigger module 102 sampling the input signal Sw at the current falling edge of the first clock signal CK1. Based on the timing characteristics of the four output signals S1 to S4 outputted by the rising edge trigger module 101 and the falling edge trigger module 102, the logic gate 150 performs an AND operation or an OR operation on the first output signal S1, the second output signal S2, the third output signal S3 and the fourth output signal S4 to generate the debounced signal Db1.

In detail, since the debounced signal Db1 is used for an active high circuit in this embodiment, the logic gate 150 adopted here is an OR gate. When either one of the first output signal S1, the second output signal S2, the third output signal S3, and the fourth output signal S4 has a digital logic value of 1, the logic gate 150 would output the debounce signal Db1 with the digital logic value of 1. In contrast, only when the first output signal S1, the second output signal S2, the third output signal S3, and the fourth output signal S4 all have digital logic values of 0, the logic gate 150 would output the debounced signal Db1 with the digital logic value of 0. Therefore, even during the time t1 to t11, the input signal Sw is disturbed by a noise 30 causing the first output signal S1 to be low between times t5 and t7 and the second output signal S2 to be low between times t6 and t8. It also causes the third output signal S3 to be low between times t7 and t9, and the fourth output signal S4 to be low between times t8 and t10. Since the digital logic values of the first output signal S1, the second output signal S2, the third output signal S3, and the fourth output signal S4 are not all Os from time ta to t11, the digital logic value of the debounced signal Db1 can be maintained at 1 between times ta and t11. Therefore, the digital logic value of the debounced signal Db1 does not bounce due to the noise 30.

The principle of the debounce circuit 100 in this embodiment can be explained as follows. The rising edge trigger module 101 can output the first output signal S1 and the third output signal S3 generated by sampling the input signal Swat two adjacent rising edges of the first clock signal CK1. The falling edge trigger module 102 can output the second output signal S2 and the fourth output signal S4 by sampling the input signal Sw at two adjacent falling edges of the first clock signal CK1. Overall, the rising edge trigger module 101 and the falling edge trigger module 102 sample the input signal Sw four times at four adjacent signal edges of the first clock signal CK1 (two rising edges and two falling edges). In addition, in the embodiment, because the debounced signal Db1 is for an active high circuit, the logic gate 150 can be an OR gate to perform OR operation on the output signals S1, S2, S3, and S4 to output the debounced signal Db1. Since the time span of the input signal Sw bouncing due to the noise 30 is not long (less than two periods T of the first clock signal CK1), the debounced signal Db1 generated by the debounce circuit 100 through the sampling and the OR operation is not affected by the noise 30.

Please refer to both FIG. 1 and FIG. 2. At time to, the voltage level of the input signal Sw is about to be switched from low to high. At time t1, the voltage level of the input signal Sw is pulled to a sufficiently high level for the rising edge trigger module 101 and the falling edge trigger module 102 to sample and output the logic value of 1. Therefore, when the first clock signal CK1 is pulled to a high level at time t1, the rising edge trigger module 101 samples the input signal Sw and the voltage level of the first output signal S1 is pulled to high. Since the response time of the rising edge trigger module 101 is not zero, there is latency between the rising edge of the first output signal S1 and the rising edge of the first clock signal CK1 (i.e., between time t1 and ta). Due to the latency, the voltage level of the first output signal S1 at time t1 remains low. When the rising edge trigger module 101 samples the first output signal S1 at time t1 to output the third output signal S3, the voltage level of the third output signal S3 remains low. When the first clock signal CK1 is pulled to low at time t2, the falling edge trigger module 102 samples the input signal Sw and the voltage level of the second output signal S2 is pulled to high. Since the response time of the rising edge trigger module 102 is not zero, there is latency between the falling edge of the second output signal S2 and the falling edge of the first clock signal CK1. Due to the latency, the voltage level of the second output signal S2 at time t2 remains low. When the falling edge trigger module 102 samples the second output signal S2 at time t2 to output the fourth output signal S4, the voltage level of the fourth output signal S4 remains low.

Then, when the first clock signal CK1 is pulled to high at time t3, the rising edge trigger module 101 samples the input signal Sw to maintain the voltage level of the first output signal S1 at high. Meanwhile, the rising edge trigger module 101 samples the first output signal S1 at time t3 to output the third output signal S3, and the voltage level of the third output signal S3 is pulled to high. Then, when the first clock signal CK1 is pulled to low at time t4, the falling edge trigger module 102 samples the input signal Sw to maintain the voltage level of the second output signal S2 at high. Meanwhile, the falling edge trigger module 102 samples the second output signal S2 at time t4 to output the fourth output signal S4, and the voltage level of the fourth output signal S4 is pulled to high.

Between times t4 and t6, the waveform of the input signal Sw is disturbed by the noise 30. When the first clock signal CK1 is pulled to high at time t5, the voltage level of the first output signal S1 sampled from the input signal Sw is pulled to low. Since the response time of the rising edge trigger module 101 is not zero, there is a latency between the falling edge of the first output signal S1 and the rising edge of the first clock signal CK1. Due to the latency, the voltage level of the first output signal S1 at time t5 remains high. When the rising edge trigger module 101 samples the first output signal S1 at time t5 to output the third output signal S3, the voltage level of the third output signal S3 remains high. Because of the waveform of the input signal Sw being affected by the noise 30, when the first clock signal CK1 is pulled to low at time t6, the voltage level of the second output signal S2 sampled from the input signal Sw is pulled to low. Since the response time of the falling edge trigger module 102 is not zero, there is a latency between the falling edge of the second output signal S2 and the falling edge of the first clock signal CK1. Due to the latency, the voltage level of the second output signal S2 at time t6 remains high. When the falling edge trigger module 102 samples the second output signal S2 at time t6 to output the fourth output signal S4, the voltage level of the fourth output signal S4 remains high.

After time t6 the noise 30 is removed, so the waveform of the input signal Sw returns to normal. Therefore, when the first clock signal CK1 is pulled to high at time t7, the rising edge trigger module 101 samples the input signal Sw and the voltage level of the first output signal S1 is pulled to high. Since the response time of the rising edge trigger module 101 is not zero, there is latency between the rising edge of the first output signal S1 and the rising edge of the first clock signal CK1. Due to the latency, the voltage level of the first output signal S1 at time t7 remains low. When the rising edge trigger module 101 samples the first output signal S1 at time t7 to output the third output signal S3, the voltage level of the third output signal S3 is pulled to low. Then, when the first clock signal CK1 is pulled to low at time t8, the falling edge trigger module 102 samples the input signal Sw and pull the voltage level of the second output signal S2 to high. Since the response time of the falling edge trigger module 102 is not zero, there is a latency between the rising edge of the second output signal S2 and the falling edge of the first clock signal CK1. Due to the latency, the voltage level of the second output signal S2 at time t8 remains low. After the falling edge trigger module 102 samples the second output signal S2 at time t8 to output the fourth output signal S4, the voltage level of the fourth output signal S4 is pulled to low.

When the first clock signal CK1 is pulled to high at time t9, the rising edge trigger module 101 samples the input signal Sw and maintains the voltage level of the first output signal S1 at high. Meanwhile, the rising edge triggers module 101 samples the first output signal S1 at time t9 to output the third output signal S3, and the voltage level of the third output signal S3 is pulled to high. Then, when the first clock signal CK1 is pulled to low at time t10, the falling edge trigger module 102 samples the input signal Sw and maintains the voltage level of the second output signal S2 at high. Meanwhile, the trigger module 102 samples the second output signal S2 at time t10 to output the fourth output signal S4, and the voltage level of the fourth output signal S4 is pulled to high.

This paragraph explains the advantage of the debounce circuit 100 comparing with the prior art. Under the same condition with the same noise 30 in FIG. 2, a debounce circuit of the prior art requires the input signal sampled has a certain number of consecutive is to outputs a debounced signal with the logic value of 1. Therefore, the debounce circuit of the prior art has to detect a plurality of is for several periods T when the noise 30 is not present after time t6 to output the debounced signal with the logic value of 1. The problem with the debounce circuit of the prior art is that the setup time is excessively shortened. In contrast, the debounced signal Db1 generated by the debounce circuit 100 of the present invention can output the logic value of 1 after time ta, so the setup time of the debounce circuit 100 is not excessively shortened by oversampling, which ensures the accuracy of the signals received by the receiver.

In the embodiment of the present invention, the rising edge trigger module 101 comprises a first D flip-flop 110 and a third D flip-flop 130, and the falling edge trigger module 102 comprises a second D flip-flop 120 and a fourth D flip-flops 140. The first D flip-flop 110 comprises a data input terminal D receiving the input signal Sw and a clock input terminal CK receiving the first clock signal CK1. It further comprises a first data output terminal Q outputting the first output signal S1. When the first clock signal CK1 is switched from 0 to 1, the logic value of the first output signal S1 outputted by the first data output terminal Q is equal to the logic value of the input signal Sw. Overall, the first D flip-flop 110 samples the input signal Sw and outputs the sampled values when the first clock signal CK1 is at the rising edge.

The second D flip-flop 120 comprises a data input terminal D receiving the input signal Sw and a clock input terminal CK receiving the second clock signal CK2. It further comprises a first data output terminal Q outputting the second output signal S2. The second clock signal CK2 has the same frequency as the first clock signal CK1 but is inverted from the first clock signal CK1. The second clock signal CK2 can be generated by inputting the first clock signal CK1 through a first inverter 122. When the second clock signal CK2 is switched from 0 to 1, the logic value of the second output signal S2 outputted by the first data output terminal Q is equal to the logic value of the input signal Sw. Overall, the second D flip-flop 120 samples the input signal Sw and outputs the sampled values when the first clock signal CK1 is at the falling edge.

The third D flip-flop 130 comprises a data input terminal D receiving the first output signal S1 and a clock input terminal CK receiving the first clock signal CK1. It further comprises a first data output terminal Q outputting the third output signal S3. When the first clock signal CK1 is switched from 0 to 1, the logic value of the third output signal S3 outputted by the first data output terminal Q is equal to the logic value of the first output signal S1. Overall, the third D flip-flop 130 samples the first output signal S1 and outputs the sampled values when the first clock signal CK1 is at the rising edge.

The fourth D flip-flop 140 comprises a data input terminal D receiving the second output signal S2 and a clock input terminal CK receiving the second clock signal CK2. It further comprises a first data output terminal Q outputting the fourth output signal S4. When the second clock signal CK2 is switched from 0 to 1, the logic value of the fourth output signal S4 outputted by the first data output terminal Q is equal to the logic value of the second output signal S2. Overall, the fourth D flip-flop 140 samples the second output signal S2 and outputs the sampled values when the first clock signal CK1 is at the falling edge.

In addition, in this embodiment, a setup terminal S, a reset terminal R, and the second data output terminal Q̅ of each D flip-flop are operated in the same manner as a general D flip-flop. The setup terminal S is used to setup the D flip-flop, and the reset terminal R is used to reset the D flip-flop. The signal outputted by the second data output terminal Q̅ and the signal outputted by the first data output terminal Q are mutually inverted signals. In this embodiment, the setup terminal S and the reset terminal R of each D flip-flop are maintained at a low voltage level, and the signal outputted by the second data output Q̅ is not processed.

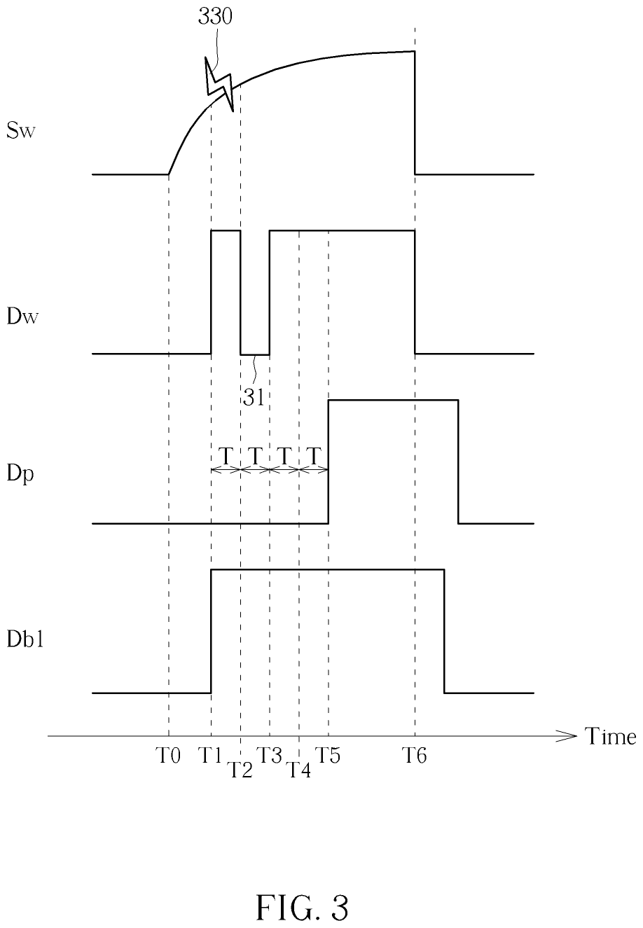

FIG. 3 shows the waveforms of four signals including the input signal Sw and the debounced signal Db1. Sw represents the original waveform of the input signal Sw in FIG. 1. Dw represents the waveform of the signal received by the receiver if debouncing process is not performed on the input signal Sw. Dp represents the output of the of the input signal Sw processed by the debounce circuit of the prior art. Db1 represents the waveform of the debounced signal Db1 outputted by the debounce circuit 100.

At time T0, the input signal Sw is about to be switched from low to high. However, due to the interference 330 between times T1 and T2, the signal Dw without debouncing process would have a low pulse 31. In contrast, even with interference 330, the signal Dp and the debounced signal Db1 would not have the pulse 31. However, since the debounce circuit of the prior art must continuously sample the input signal Sw to get consecutive 1s, the signal Dp is pulled to a high level at time T5. Therefore, the setup time of the device using the debounce circuit of the prior art is excessively shortened due to oversampling. The period of the first clock signal CK1 is T, and the time span between times T1 and T5 is approximately four periods 4T in the first clock signal CK1. In contrast, the debounce circuit 100 of the present invention adopts the first D flip-flop 110 and the third D flip-flop 130 to sample when the first clock signal CK1 is at the rising edges, and adopts the second D flip-flop 120 and the fourth D flip-flop 140 to sample when the first clock signal CK1 is at the falling edges. Thus, the sample rate is greater than which of the prior art, and the frequency of the first clock signal CK1 does not need to be excessively high. Assuming that the frequency of the input signal Sw is fa, and the frequency of the first clock signal CK1 and the second clock signal CK2 is fb, then the relation of the frequencies is 2fa≤fb≤5fa. In other words, a frequency fb of the first clock signal CK1 and the second clock signal CK2 may be greater than or equal to twice the frequency of the input signal Sw and may be less than or equal to five times the frequency of the input signal Sw. In addition, the debounced signal Db1 output by the debounce circuit 100 is pulled to high at time T1, and the debounced signal Db1 remains high at least until time T6. Therefore, with the debounce circuit 100 of the present invention, the setup time of the device is not excessively shortened, and in which ensures the accuracy of the signal received.

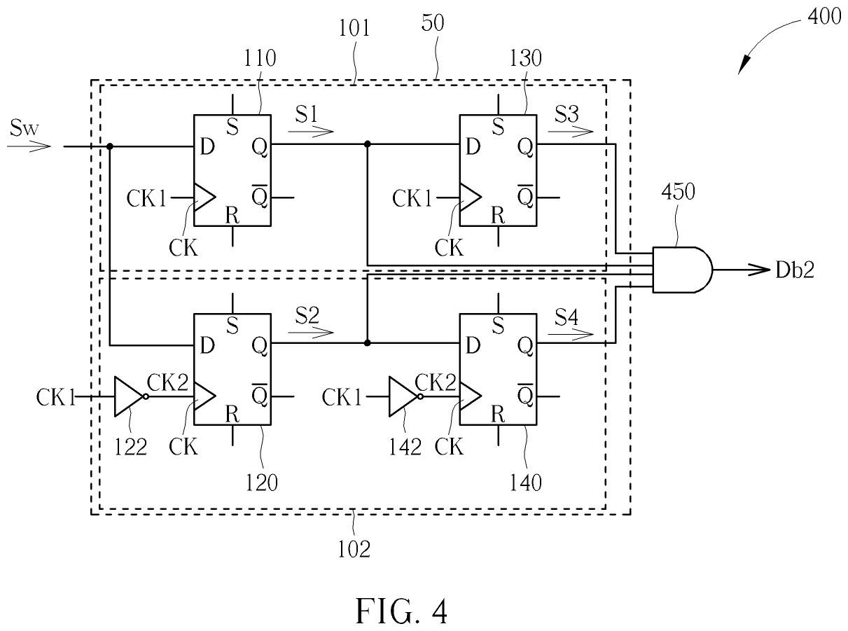

FIG. 4 is a circuit diagram of a debounce circuit 400 of another embodiment. The major difference between the debounce circuit 400 and the debounce circuit 100 is that a debounced signal Db2 outputted by the debounce circuit 400 is used for an active low circuit, and the logic gate 150 is replaced by a logic gate 450. The logic gate 450 is an AND gate for performing an AND operation on a first output signal S1, a second output signal S2, a third output signal S3, and a fourth output signal S4 to output to a debounced signal Db2. Therefore, only when the first output signal S1, the second output signal S2, the third output signal S3, and the fourth output signal S4 are all at a high voltage level, the debounced signal Db2 would be at a high voltage level which represents the logic value of 1. In contrast, if any of the first output signal S1, the second output signal S2, the third output signal S3, or the fourth output signal S4 is at a low level, the debounced signal Db2 would be at a low level, which represents the logic value of 0.

The debounce circuit 400 also includes a sampling circuit 50. The sampling circuit 50 includes a rising edge trigger module 101 and a falling edge trigger module 102. The rising edge trigger module 101 is configured to sample the input signal Sw to determine the voltage level of the first output signal S1 when the first clock signal CK1 is at the rising edge and to sample the first output signal S1 to determine the voltage level of the third output signal S3. The falling edge trigger module 102 is configured to sample the input signal Sw to determine the voltage level of the second output signal S2 when the first clock signal CK1 is at the falling edge and to sample the second output signal S2 to determine the voltage level of the fourth output signal S4. Similarly, the rising edge trigger module 101 can include a first D flip-flop 110 and a third D flip-flop 130, and the falling edge trigger module 102 can include a second D flip-flop 120 and a fourth D flip-flop 140.

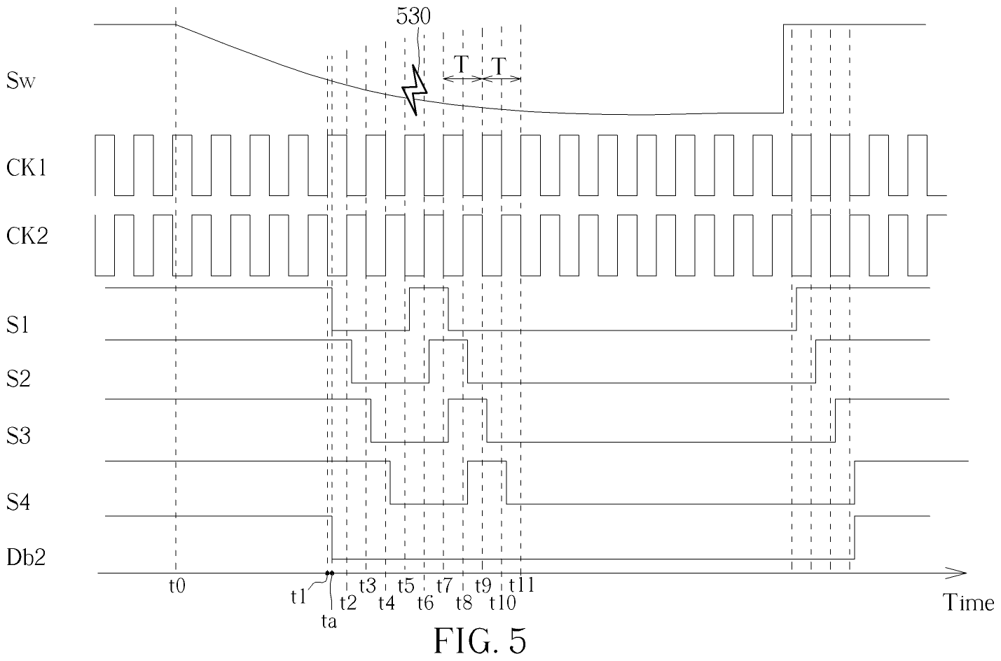

FIG. 5 is a timing diagram of various signals of the debounce circuit 400 in FIG. 4. The rising edge trigger module 101 samples the input signal Sw and the first output signal S1 at the rising edge of the first clock signal CK1 to determine the voltage level of the first output signal S1 and the voltage level of the third output signal S3. Therefore, the waveform of the third output signal S3 will lag behind the waveform of the first output signal S1 by a period T of the first clock signal CK1. Similarly, the falling edge trigger module 102 samples the input signal Sw and the second output signal S2 at the falling edge of the first clock signal CK1 to determine the voltage level of the second output signal S2 and the voltage level of the fourth output signal S4. Therefore, the waveform of the fourth output signal S4 will lag behind the waveform of the second output signal S2 by a period T of the first clock signal CK1. Similarly, the logic gate 450 performs an AND operation on the first output signal S1, the second output signal S2, the third output signal S3 and the fourth output signal S4 to generate the debounced signal Db2.

In detail, since the debounced signal Db2 is for an active low circuit in this embodiment, the logic gate 450 adopted here is an AND gate. When either one of the first output signal S1, the second output signal S2, the third output signal S3, and the fourth output signal S4 has a digital logic value of 0, the logic gate 450 would output the debounce signal Db2 with the digital logic value of 0. In contrast, only when the first output signal S1, the second output signal S2, the third output signal S3, and the fourth output signal S4 all have digital logic values of 1, the logic gate 450 would output the debounced signal Db2 with the digital logic value of 1. Therefore, even during the time t1 to t11, the input signal Sw is disturbed by a noise 530 causing the first output signal S1 to be high between times t5 and t7 and the second output signal S2 to be high between times t6 and t8. It also causes the third output signal S3 to be high between times t7 and t9, and the fourth output signal S4 to be high between times t8 and t10. Since the digital logic values of the first output signal S1, the second output signal S2, the third output signal S3, and the fourth output signal S4 are not all is at the times ta to t11, the digital logic value of the debounced signal Db1 can be maintained at 0 between times ta and t11. Therefore, the digital logic value of the debounced signal Db1 does not bounce due to the noise 530.

This paragraph explains the advantage of the debounce circuit 400 comparing with the prior art. Under the same condition with the same noise 530 in FIG. 5, a debounce circuit of the prior art requires the input signal sampled has a certain number of consecutive Os to outputs a debounced signal with a logic value of 0. Therefore, the debounce circuit of the prior art has to detect a plurality of is for several periods T when the no noise 530 present after time t6 to output a debounced signal with a logic value of 0. The problem with the debounce circuit of the prior art is that the setup time is excessively shortened. In contrast, the debounced signal Db2 generated by the debounce circuit 400 of the present invention can output the logic value of 0 after time ta, so the setup time of the debounce circuit 400 is not excessively shortened by oversampling, which ensures the accuracy of the signals received by the receiver.

Please refer to both FIG. 4 and FIG. 5. At time to, the voltage level of the input signal Sw is about to be switched from high to low. At time t1, the voltage level of the input signal Sw is pulled to a sufficiently low level for the rising edge trigger module 101 and the falling edge trigger module 102 to output the logic value of 0. Therefore, when the first clock signal CK1 is pulled to a high level at time t1, the rising edge trigger module 101 samples the input signal Sw and the voltage level of the first output signal S1 is pulled to low. Since the response time of the rising edge trigger module 101 is not zero, there is a latency between the rising edge of the first output signal S1 and the rising edge of the first clock signal CK1 (i.e., between times t1 and ta). Due to the latency, the voltage level of the first output signal S1 at time t1 remains high. When the rising edge trigger module 101 samples the first output signal S1 at time t1 to output the third output signal S3, the voltage level of the third output signal S3 remains high. When the first clock signal CK1 is pulled to low at time t2, the falling edge trigger module 102 samples the input signal Sw and the voltage level of the second output signal S2 is pulled to low. Since the response time of the rising edge trigger module 102 is not zero, there is latency between the rising edge of the second output signal S2 and the falling edge of the first clock signal CK1. Due to the latency, the voltage level of the second output signal S2 at time t2 remains high. When the falling edge trigger module 102 samples the second output signal S2 at time t2 to output the fourth output signal S4, the voltage level of the fourth output signal S4 remains high.

Then, when the first clock signal CK1 is pulled to high at time t3, the rising edge trigger module 101 samples the input signal Sw to maintain the voltage level of the first output signal S1 at low. Meanwhile, the rising edge trigger module 101 samples the first output signal S1 at time t3 to output the third output signal S3, and the voltage level of the third output signal S3 is pulled to low. Then, when the first clock signal CK1 is pulled to low at time t4, the falling edge trigger module 102 samples the input signal Sw to maintain the voltage level of the second output signal S2 at low. Meanwhile, the falling edge trigger module 102 samples the second output signal S2 at time t4 to output the fourth output signal S4, and the voltage level of the fourth output signal S4 is pulled to low.

Between times t4 and t6, the waveform of the input signal Sw is disturbed by the noise 530. When the first clock signal CK1 is pulled to high at time t5, the voltage level of the first output signal S1 sampled from the input signal Sw is pulled to high. Since the response time of the rising edge trigger module 101 is not zero, there is latency between the rising edge of the first output signal S1 and the rising edge of the first clock signal CK1. Due to the latency, the voltage level of the first output signal S1 at time t5 remains low. After the rising edge trigger module 101 samples the first output signal Slat time t5 to output the third output signal S3, the voltage level of the third output signal S3 remains low. Similarly, the waveform of the input signal Sw is disturbed by the noise 530. When the first clock signal CK1 is pulled to low at time t6, the voltage level of the second output signal S2 sampled from the input signal Sw is pulled to high. Since the response time of the falling edge trigger module 102 is not zero, there is latency between the rising edge of the second output signal S2 and the falling edge of the first clock signal CK1. Due to the latency, the voltage level of the second output signal S2 at time t6 remains low. After the falling edge trigger module 102 samples the second output signal S2 at time t6 to output the fourth output signal S4, the voltage level of the fourth output signal S4 remains low.

After time t6 the noise 530 is removed, so the waveform of the input signal Sw returns to normal. Therefore, when the first clock signal CK1 is pulled to high time t7, the rising edge trigger module 101 samples the input signal Sw and the voltage level of the first output signal S1 is pulled to low. Since the response time of the rising edge trigger module 101 is not zero, there is latency between the falling edge of the first output signal S1 and the rising edge of the first clock signal CK1. Due to the latency, the voltage level of the first output signal S1 at time t7 remains high. After the rising edge trigger module 101 samples the first output signal S1 at time t5 to output the third output signal S3, the voltage level of the third output signal S3 is pulled to high. Then, when the first clock signal CK1 is pulled to low at time t8, the falling edge trigger module 102 samples the input signal Sw and the voltage level of the second output signal S2 is pulled to low. Since the response time of the falling edge trigger module 102 is not zero, there is latency between the rising edge of the second output signal S2 and the falling edge of the first clock signal CK1. Due to the latency, the voltage level of the second output signal S2 at time t8 remains high. After the falling edge trigger module 102 samples the second output signal S2 at time t8 to output the fourth output signal S4, the voltage level of the fourth output signal S4 is pulled to high.

When the first clock signal CK1 is pulled to high at time t9, the rising edge trigger module 101 samples the input signal Sw and maintains the voltage level of the first output signal S1 at low. Meanwhile, the rising edge triggers module 101 samples the first output signal S1 at time t9 to output the third output signal S3, and the voltage level of the third output signal S3 is pulled to low. Then, when the first clock signal CK1 is pulled to low at time t10, the falling edge trigger module 102 samples the input signal Sw and maintains the voltage level of the second output signal S2 at low. Meanwhile, the trigger module 102 samples the second output signal S2 at time t10 to output the fourth output signal S4, and the voltage level of the fourth output signal S4 is pulled to low.

In summary, the debounce circuit of the present invention includes a rising edge trigger module, a falling edge trigger module and a logic gate. The rising edge trigger module can output two signals generated by sampling the input signal at two adjacent rising edges of the clock signal, and the falling edge trigger module can output two signals generated by sampling the input signal at two adjacent falling edges of the clock signal. Overall, the rising edge trigger module and the falling edge trigger module sample the input signal four times at four adjacent signal edges of the clock signal. In addition, the present invention determines the logic gate to be an OR gate or an AND gate respectively based on whether the debounced signal is used for active high circuit or active low circuit and performs an OR operation or an AND operation on the outputted signals to generate the debounced signal. Since time span of the input signal bouncing due to a noise is not excessively long (less than the period of the two sampling clocks), the debounced signal generated by the debounce circuit of the present invention is not affected by the noise. Furthermore, since the debounce circuit of the present invention uses the rising edge trigger module to sample at the rising edge of the clock signal and uses the falling edge trigger module to sample at the falling edge of the clock signal, the sample rate is greater so the frequency of the clock signal for sampling does not need to be excessively high. In addition, the setup time of the debounce circuit of the present invention is not excessively shortened due to oversampling, in which ensures the accuracy of the signal received.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A debounce circuit comprising:
a sampling circuit configured to sample an input signal four times at two adjacent rising edges and two adjacent falling edges of a first clock signal to determine a voltage level of a first output signal, a voltage level of a second output signal, a voltage level of a third output signal and a voltage level of a fourth output signal, wherein at least one of the two adjacent rising edges is between the two adjacent falling edges, and at least one of the two adjacent falling edges is between the two adjacent rising edges; and
a logic gate configured to perform an AND operation or an OR operation on the first output signal, the second output signal, the third output signal, and the fourth output signal to output a debounced signal.

2. The debounce circuit of claim 1, wherein the sampling circuit comprises:
a rising edge trigger module configured to sample the input signal to determine the voltage level of the first output signal and to sample the first output signal to determine the voltage level of the third output signal when the first clock signal is at a rising edge; and
a falling edge trigger module configured to sample the input signal to determine the voltage level of the second output signal and to sample the second output signal to determine the voltage level of the fourth output signal when the first clock signal is at a falling edge.

3. The debounce circuit of claim 2, wherein the rising edge trigger module comprises a first D flip-flop and a third D flip-flop, and the falling edge trigger module comprises a second D flip-flop and a fourth D flip-flop;
wherein the first D flip-flop comprises:
a data input terminal configured to receive the input signal;
a clock input terminal configured to receive the first clock signal; and
a first data output terminal configured to output the first output signal;
wherein the second D flip-flop comprises:
a data input terminal configured to receive the input signal;
a clock input terminal configured to receive the second clock signal having a same frequency as the first clock signal and a phase opposite to the first clock signal; and
a first data output terminal configured to output the second output signal;
wherein the third D flip-flop comprises:
a data input terminal configured to receive the first output signal;
a clock input terminal configured to receive the first clock signal; and
a first data output terminal configured to output the third output signal; and
wherein the third D flip-flop comprises:
a data input terminal configured to receive the second output signal;
a clock input terminal configured to receive the second clock signal; and
a first data output terminal configured to output the fourth output signal.

4. The debounce circuit of claim 3, wherein the falling edge trigger module further comprises an inverter having an input terminal configured to receive the first clock signal and an output terminal configured to output the second clock signal.

5. The debounce circuit of claim 4, wherein the output terminal of the inverter is coupled to the clock input terminal of the second D flip-flop and the clock input terminal of the fourth D flip-flop.

6. The bounce circuit of claim 3, wherein the falling edge trigger module further comprises:
a first inverter having an input terminal configured to receive the first clock signal and an output terminal coupled to the clock input terminal of the second D flip-flop; and
a second inverter having an input terminal configured to receive the first clock signal and an output terminal coupled to the clock input terminal of the fourth D flip-flop.

7. The debounce circuit of claim 1, wherein the logic gate is an OR gate configured to perform an OR operation on the first output signal, the second output signal, the third output signal, and the fourth output signal to output the debounced signal.

8. The debounce circuit of claim 1, wherein the logic gate is an AND gate configured to perform an AND operation on the first output signal, the second output signal, the third output signal, and the fourth output signal to output the debounced signal.

9. The debounce circuit of claim 1, wherein a frequency of the first clock signal is less than or equal to five times a frequency of the input signal.

10. The debounce circuit of claim 1, wherein the frequency of the first clock signal is greater than or equal to two times a frequency of the input signal.
